(19) United States
(12) Patent Application Publication
(10) Pub. No.: US 2023/0331240 A1
(43) Pub. Date: Oct. 19, 2023

(54) SYSTEM AND METHOD FOR TRAINING AT LEAST ONE POLICY USING A FRAMEWORK FOR ENCODING HUMAN BEHAVIORS AND PREFERENCES IN A DRIVING ENVIRONMET

(71) Applicant: Toyota Research Institute, Inc., Los Altos, CA (US)

(72) Inventors: Jonathan DeCastro, Arlington, MA (US); Guy Rosman, Newton, MA (US); Simon A.I. Stent, Cambridge, MA (US); Emily Sumner, Mountain View, CA (US); Shabnam Hakimi, San Francisco, CA (US); Deepak Edakkattil Gopinath, Washington, DC (US); Allison Morgan, Oakland, CA (US)

(73) Assignees: Toyota Research Institute, Inc., Los Altos, CA (US); Toyota Jidosha Kabushiki Kaisha, Toyota-shi Aichi-ken (JP)

(21) Appl. No.: 18/098,776

(22) Filed: Jan. 19, 2023

Related U.S. Application Data
(60) Provisional application No. 63/331,003, filed on Apr. 14, 2022.

(51) Int. Cl. B60W 40/09; B60W 40/105; B60W 50/14

(52) U.S. Cl. CPC B60W 40/09; B60W 40/105; B60W 50/14; B60W 2050/143

(57) ABSTRACT

Disclosed are systems and methods for training at least one policy using a framework for encoding human behaviors and preferences in a driving environment. In one example, the method includes the steps of setting parameters of rewards and a Markov Decision Process (MDP) of the at least one policy that models a simulated human driver of a simulated vehicle and an adaptive human-machine interface (HMI) system configured to interact with each other and training the at least one policy to maximize a total reward based on the parameters of the rewards of the at least one policy.

### CROSS-REFERENCE TO RELATED APPLICATION

This application claims priority to U.S. Provisional Patent Application No. 63/331,003 filed Apr. 14, 2022, the contents of which are hereby incorporated by reference in its entirety.

### TECHNICAL FIELD

The subject matter described herein relates, in general, to systems and methods for modeling and studying human-machine teaming in the context of driving.

### BACKGROUND

The background description provided is to present the context of the disclosure generally. To the extent it may be described in this background section, the work of the inventor and aspects of the description that may not otherwise qualify as prior art at the time of filing are neither expressly nor impliedly admitted as prior art against the present technology.

Some vehicles have sensors and processing capabilities that can detect objects in the environment and the movement of these objects within the environment. Using this information, these vehicles may be able to alert the driver of a potentially unsafe situation so that the driver can take corrective action. In more advanced systems, some vehicles can essentially take control of the vehicle to avoid the potentially unsafe situation.

However, effectively communicating potentially unsafe situations to drivers can be particularly challenging. For example, some drivers are easily distracted and may benefit from earlier and continual alerts regarding the unsafe situation. However, other drivers are less distracted and may not benefit from earlier and/or continual alerts regarding the unsafe situation. These types of drivers may find the system annoying and/or lose trust in the system, effectively reducing the usefulness of the system. Personalized interventions may be useful to provide effective assistance that helps the driver and does not counteract their intentions.

### SUMMARY

This section generally summarizes the disclosure and is not a comprehensive explanation of its full scope or all its features.

In one embodiment, a method for training at least one policy using a framework for encoding human behaviors and preferences in a driving environment includes the steps of setting parameters of rewards and a Markov Decision Process (MDP) of the at least one policy that models a simulated human driver of a simulated vehicle and an adaptive human-machine interface (HMI) system configured to interact with each other and training the at least one policy to maximize a total reward based on the parameters of the rewards of the at least one policy. The at least one policy may be a joint policy that models actions of the simulated human driver and the adaptive HMI system or separate policies that separately model actions of the simulated human driver and the adaptive HMI system.

In another embodiment, a system for training at least one policy using a framework for encoding human behaviors and preferences in a driving environment includes a processor and a memory in communication with the processor. The memory stores instructions that, when executed by the processor, cause the processor to set parameters of rewards and an MDP of the at least one policy that models a simulated human driver of a simulated vehicle and an adaptive HMI system configured to interact with each other, and train the at least one policy to maximize a total reward based on the parameters of the rewards of the at least one policy. Like before, the at least one policy may be a joint policy that models actions of the simulated human driver and the adaptive HMI system or separate policies that separately model actions of the simulated human driver and the adaptive HMI system.

In yet another embodiment, a non-transitory computer-readable medium stores instructions for training at least one policy using a framework for encoding human behaviors and preferences in a driving environment. When executed by one or more processors, the instructions cause the one or more processors to set parameters of rewards and an MDP of the at least one policy that models a simulated human driver of a simulated vehicle and an adaptive HMI system configured to interact with each other and train the at least one policy to maximize a total reward based on the parameters of the rewards of the at least one policy. Again, the at least one policy may be a joint policy that models actions of the simulated human driver and the adaptive HMI system or separate policies that separately model actions of the simulated human driver and the adaptive HMI system.

Further areas of applicability and various methods of enhancing the disclosed technology will become apparent from the description provided. The description and specific examples in this summary are intended for illustration only and are not intended to limit the scope of the present disclosure.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates a process flow for training at least one policy using a framework for encoding human behaviors and preferences in a driving environment.

FIG. 2 illustrates a block diagram of a system for training at least one policy using a framework for encoding human behaviors and preferences in a driving environment.

FIG. 3A illustrates a transition system for a distracted driving model that governs the tendency of a driver to become distracted and comply with or ignore an intervention.

FIG. 3B illustrates a transition system for a driving model that models the vehicle's actions based on the physical environment and distraction state.

FIG. 4A illustrates data traces for a simulated human driver who is less cautious and unwilling to accept vehicle alerts.

FIG. 4B illustrates data traces for a simulated human driver who is more cautious and willing to accept vehicle alerts, respectively.

FIG. 5 illustrates a method for training at least one policy using a framework for encoding human behaviors and preferences in a driving environment.

### DETAILED DESCRIPTION

Described are systems and methods for training at least one policy using a framework for encoding human behaviors and preferences in a driving environment. Moreover, in one example, a lightweight simulation and modeling framework process studying human-machine teaming is utilized in the context of driving. The framework accelerates the development of adaptive artificial intelligence (AI) systems that can respond to individual driver states, traits, and preferences by serving as a data generation engine and training environment for learning personalized human AI teaming policies. The framework supports modeling human behaviors and their preferences for receiving AI assistance to support various tasks such as data generation, algorithm prototyping, and learning interaction policies.

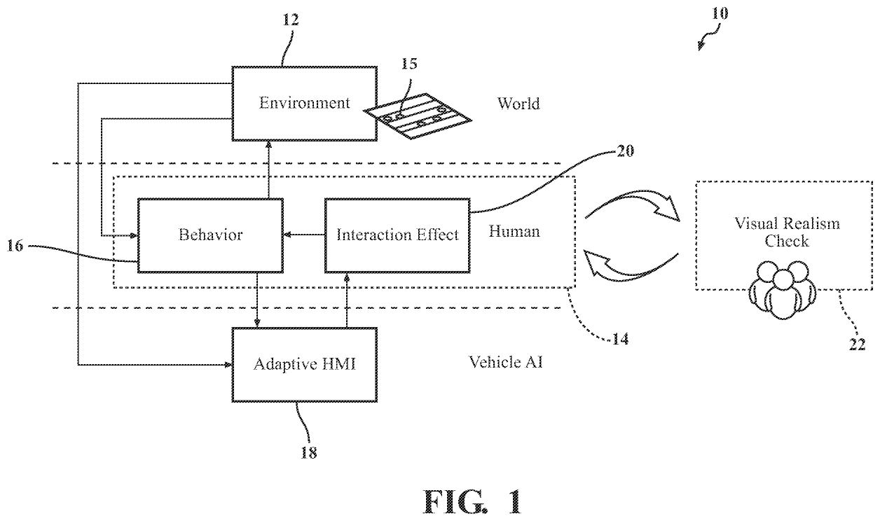

FIG. 1 illustrates a basic process flow 10 of the framework utilized to train the at least one policy for encoding human behaviors and preferences in a driving environment. Details regarding the basic process flow 10 will be described later in this description. Here, the driving environment 12 may be based on a simulated environment that may be a highway simulation model, built as an environment for developing different machine learning based systems and may include simulated vehicles. In one example, the environment may be based on a standardized framework, such as the OpenAI Gym framework.

A simulated human driver 14 may have certain behaviors 16 that may be impacted by the driving environment 12 and an adaptive human-machine interface (HMI) system 18 as well as an interaction effect 20. The driving environment 12 is interfaced via behaviors 16 and the interaction effect 20 to support imperfect human drivers in various conditions. The adaptive HMI system 18, as will be explained in greater detail later in this description, can provide the simulated human driver 14 that pilots a simulated vehicle 15 that is part of the driving environment 12 with alerts to improve the driving habits of the simulated human driver 14. The simulated human driver 14 and the adaptive HMI system 18 are configured to interact with each other and may have separate policies or even a joint policy that can be trained to maximize a total reward based on the parameters of the rewards of the policy. Once trained, the simulated human driver 14 and the adaptive HMI system 18 can be evaluated using a visual realism check 22, wherein comparisons are made to actual human behavior.

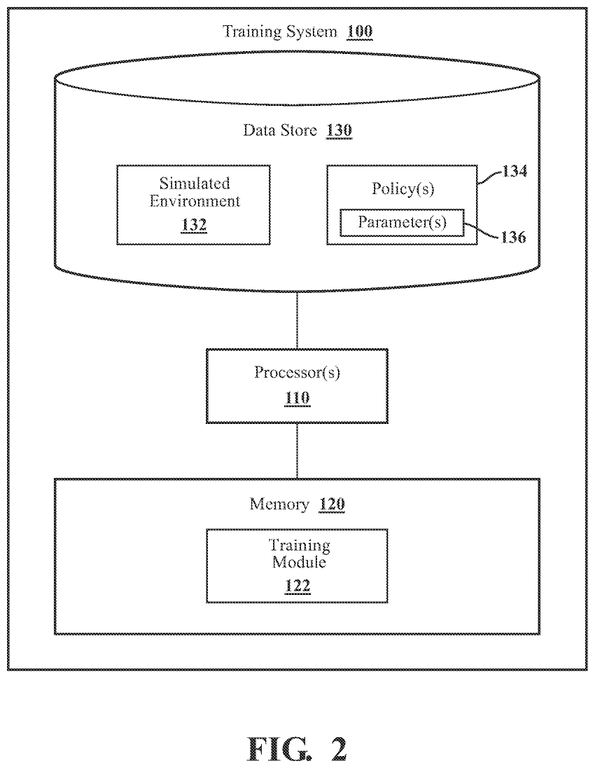

Referring to FIG. 2, the training of the separate policies or joint policy of the simulated human driver 14 and the adaptive HMI system 18 may be performed by a training system 100. The training system 100 may be a general or specific-purpose computer that can perform any of the various functions described in this description. As shown, the training system 100 includes one or more processor(s) 110. Accordingly, the processor(s) 110 may be a part of the training system 100, or the training system 100 may access the processor(s) 110 through a data bus or another communication path. In one or more embodiments, the processor(s) 110 is an application-specific integrated circuit configured to implement functions associated with a training module 122. In general, the processor(s) 110 is an electronic processor, such as a microprocessor, capable of performing various functions described herein.

In one embodiment, the training system 100 includes a memory 120 that stores the training module 122. The memory 120 may be a random-access memory (RAM), read-only memory (ROM), a hard disk drive, a flash memory, or other suitable memory for storing the training module 122. For example, the training module 122 is computer-readable instructions that, when executed by the processor(s) 110, cause the processor(s) 110 to perform the various functions disclosed herein.

Furthermore, in one embodiment, the training system 100 includes a data store 130. The data store 130 is, in one embodiment, an electronic data structure such as a database that is stored in the memory 120 or another memory and that is configured with routines that the processor can execute (s) 110 for analyzing stored data, providing stored data, organizing stored data, and so on. Thus, in one embodiment, the data store 130 stores data used by the training module 122 in executing various functions. In one embodiment, the data store 130 includes the simulated environment 132, which may be similar to the driving environment 12. As such, the simulated environment 132 may be a highway simulation model built as an environment for developing different machine learning based systems. As mentioned before, the environment may be based on a standardized framework, such as the OpenAI Gym framework. However, it should be understood that the simulated environment 132 can take any one of a number of different forms simulating a number of different environments and may be based on a number of different frameworks.

Also stored on the data store 130 may be one or more policies 134. The one or more policies 134 may be separate policies that model the simulated human driver 14 and the adaptive HMI system 18. The one or more policies 134 may be separate policies that separately model the simulated human driver 14 and the adaptive HMI system 18 or may be a joint policy that essentially models both.

The actions of the one or more policies 134 can include human-initiated vehicle actions by the simulated human driver 14 and intervention actions by the adaptive HMI system 18. In one example, the human-initiated vehicle actions may include speeding up the simulated vehicle 15, slowing down the simulated vehicle 15, causing the simulated vehicle 15 to move left, causing the simulated vehicle 15 to move right, and/or maintaining the speed of the simulated vehicle 15. The intervention actions may include providing an alert to the simulated human driver and not providing the alert to the simulated human driver. Of course, it should be understood that the actions of the one or more policies 134 can vary from application to application and should not be limited to just the actions described.

The one or more policies 134 may include one or more parameters 136 that are parameters of the rewards and a Markov Decision Process (MDP). As will be explained in more detail later in this description, the one or more parameters 136 may include cautiousness exhibited by the simulated human driver, a likelihood of the simulated human driver becoming distracted and attentive, and a willingness of the simulated human driver to be influenced by an external alert issued by the adaptive HMI system. Again, the examples of the one or more parameters 136 are just examples and can include different parameters as well.

Ultimately, the purpose of the training system 100 is to train the one or more policies 134 to maximize the total reward based on the parameters 136 of the one or more policies 134. This allows for the modeling of behaviors of a human for receiving AI assistance to support various tasks such as data generation, algorithm prototyping, and learning interaction policies. It is noted that this description primarily focuses on modeling human distraction, the training system 100 can also be utilized to train one or more policies 134 that can model other driver-specific behaviors, such as attention shifts, the effects of age, alarm fatigue, and other physical and cognitive impairments.

The model is framed as a reinforcement learning (RL) problem, which solves for the one or more policies 134, which is a function mapping observations by the agent to actions taken on the part of the agent. Regarding their higher-level goals and constraints in terms of a system of rewards, the agent (the one or more policies 134) represents both the simulated human driver 14 and the adaptive HMI system 18 operating together (joint policy) or as two policies that interact with one another.

The one or more policies 134 are learned from observations of the world based on collected experience and are gradually improved through maximization of a total reward for each roll-out generated by the one or more policies 134 as it is trained. Observations are potentially corrupted measurements of the state. The model of the human is expressed as the MDP, which specifies the probability of transitioning from one state to another, along with any rewards (e.g., speed preferences) or penalties (e.g., collisions) collected along the way. A policy gradient method may be adopted to train the one or more policies 134, such as the proximal policy optimization (PPO) algorithm.

To augment the existing environments to capture human factors, parameter(s) 136 are introduced into the driving environment 12 to capture: (a) the cautiousness exhibited by the driver, (b) the likelihood of the driver becoming distracted and attentive, and (c) and the willingness of a driver to be influenced by an external alert issued by the adaptive HMI system 18. The observations fed into the one or more policies 134 encode the positions and velocities of nearby vehicles as lidar observations. Lidar-like representations resemble a human's perception system in a coarse sense (and therefore, it is sensible to use such representations for training a driver policy), and it is also true to the vehicle's on-board perception system (justifying its use for training the vehicle AI's intervention policy). The parameter that encodes the driver's cautiousness level, referred to as obstacle inflation factor, w, inflates the spatial footprint of the surrounding vehicles and, as a result, the distance to the surrounding vehicles will be reduced proportionally. This models the tendency of drivers to maintain different levels of space with other cars depending on their individual preferences.

The processor(s) 110, upon executing the appropriate instructions stored within the training module 122, can set the one or more parameters 136 to train the one or more policies 134 for the simulated human driver 14 and the adaptive HMI system 18. As mentioned before, when the one or more policies 134 is a joint policy, the actions of the joint policy can include both includes human-initiated vehicle actions (vₜ^{H}) by the simulated human driver 14 and intervention actions (vₜ^{A}) by the adaptive HMI system 18. For vₜ^{H}, the action space may include a discrete set of semantic actions comprising {speed up, slow down, keep speed, move left, move right}, where the first two actions result in changes in speed, while the last two bring about lane changes. The action space for vₜ^{A} may be binary and includes a discrete set of intervention actions given by {alert, no alert}. The mechanism by which vₜ^{A} affects the vehicle actions applied to the vehicle is facilitated by the intermediate distraction and alert-acceptance model described later in this description.

A vehicle class may be introduced into the driving environment 12 to encapsulate distraction and intervention acceptance models. The simulated vehicle 15 that the RL agent controls is modeled as a PilotedMDPVehicle. PilotedMDPVehicle takes the joint policy action as input and updates its state in a three-step process. First, the intervention action affects the acceptance state of the vehicle. Second, the distraction state is updated using the subsumed distraction model. Third, the vehicle action conditioned on the distracted state is applied to the vehicle. Finally, the behavior of the other vehicles on the road is modeled using the intelligent model. The initial speeds are uniformly distributed in a range within the prescribed speed limits of the road on which they are spawned.

The distraction model can capture a variety of phenomena observed in driving. The distraction model can capture momentary lapses in driving, such as when a driver is engaged in a secondary task (e.g., cellphone use) or is otherwise inattentive to the road. The distraction model can also encompass delays in action that might result in the driver being engaged in conversation or in a state of high cognitive load. In the framework, the non-rational behavior exhibited by the driver is modeled primarily by the interaction of two binary random variables: the distraction state dₜ and the acceptance state iₜ.

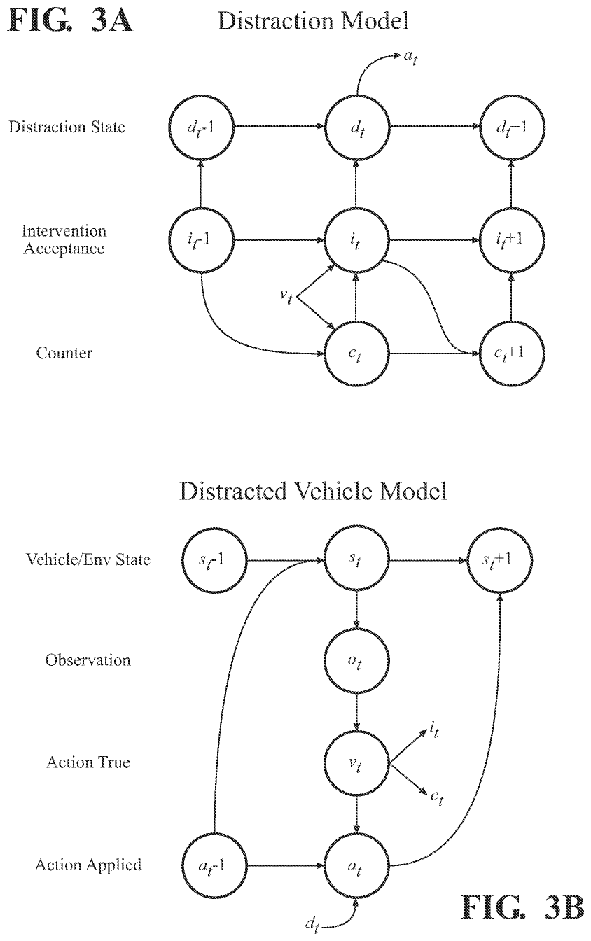

Referring to FIGS. 3A and 3B, dₜ encodes whether the driver is distracted or attentive, and the acceptance state, while iₜ encodes the driver's inclination to be influenced by the vehicle AI's alert signal. The downstream effect of responding to an alert is that it indirectly affects the transition dynamics of the distraction state. With specific attention to FIG. 3A, the true action vₜ includes two components: the vehicle action vₜ^{H} and the action of the adaptive HMI system 18 vₜ^{A}∈{alert, no_alert}. A counter variable cₜ may be introduced to encode how long a successful intervention by the adaptive HMI system 18 remains in effect. When the adaptive HMI system 18 issues an alert, the effect of the alert persists for a fixed time window, referred to as the intervention effectiveness window of size N, during which the acceptance state remains 1. The transitions for the intervention effect variable iₜ and cₜ are determined by the following equations:

$$if {i}_{t - 1} = 0 then \{ \begin{matrix}{i}_{t} = 1 , {c}_{t} = 0 & if {v}_{t}^{A} = alert \\ {i}_{t} = 0 , {c}_{t} = 0 & if {v}_{t}^{A} = no\_alert\end{matrix} \qquad ( 1 )$$

$$if {i}_{t - 1} = 1 , {v}_{t}^{A} = alert , then {c}_{t} = 0 and {i}_{t} = 1 \qquad ( 2 )$$

$${c}_{t} = ( {c}_{t - 1} + 1 ) mod N , \{ \begin{matrix}{i}_{t} = 1 & if {c}_{t - 1} < N - 1 \\ {i}_{t} = 0 & if {c}_{t - 1} = N - 1\end{matrix} \qquad ( 3 )$$

Equations (1) and (2) capture the behavior that, when the simulated human driver 14 complies with an alert from the adaptive HMI system 18, their acceptance state is always set to be 1, regardless of the acceptance state at the previous time step. Additionally, cₜ is set to be 0, indicating that the intervention from the adaptive HMI system 18 has been re-triggered. If the acceptance state of the simulated human driver 14 is 0, it continues to be 0 if no alert has been received. In Equation (3), if the acceptance state is already 1 (which implies that the alert from the adaptive HMI system 18 was already accepted by the simulated human driver 14 at an earlier time step), then the acceptance state continues to be 1 (that is, the alert continues to affect the simulated human driver 14) as long as cₜ remains within the intervention effectiveness window. Once cₜ is greater than the window size, the acceptance state is reset to 0 if no more alerts are accepted.

In the current implementation, the distraction variable dₜ evolves as a controlled Markov chain whose transition probabilities are modulated according to the acceptance state iₜ of the simulated human driver 14. The amount of modulation is controlled by a parameter γ, which captures the willingness of the simulated driver 14 to be influenced by the alert issued by the adaptive HMI system 18. Upon accepting the alert from the adaptive HMI system 18, the baseline transition probabilities of the distraction state Markov chain are modulated so that the probability of becoming distracted is reduced and of becoming more attentive is increased. Specifically, if β∈(0, 1) is the baseline probability of transitioning from an attentive state (dₜ−1=0) to a distracted state (dₜ=1), the conditional (modified according to the acceptance state) transition probabilities for the Markov model is given by:

p(dₜ=1|dₜ₋₁=0)=max(0,β−γ [symbol] (iₜ=1)) (4)

where γ is the intervention effectiveness factor and [symbol] (·) is the indicator function. Likewise, the probability of transitioning from a distracted to an attentive state becomes higher when the simulated human driver 14 is willing to accept the alert issued by the adaptive HMI system 18. alert. Therefore,

p(dₜ=0|dₜ₋₁=1)=min(1,α+γ [symbol] (iₜ=1)) (5)

where α is the baseline probability of transitioning from a distracted to an attentive state.

From the above equations, one can see that if the simulated human driver 14 accepts an alert from the adaptive HMI system 18, the acceptance state will be set to 1. As a result, the transition probabilities in Equations (4) and (5) are modulated. This modulation remains in effect for at least N time steps. In the framework, at every timestep t, first cₜ is updated, followed by the acceptance state iₜ, and then finally the distraction variable dₜ.

For t>0, the value of dₜ, the distraction state, affects the applied vehicle action at as follows:

$${a}_{t} = \{ \begin{matrix}{a}_{t - 1} & if {d}_{t} = 1 \\ {v}_{t}^{H} & if {d}_{t} = 0\end{matrix} \qquad ( 6 )$$

with a₀=v₀^{H}.

As for the reward structure, Table 1 shows the full list of driving-related rewards used by the joint human-vehicle AI model capturing one or more policies 134 trained for the actions of both the simulated human driver 14 and adaptive HMI system 18.

TABLE 1
Driving-related rewards for the joint human-vehicle AI system

| | |
|---|---|
| R_{coll} | C_{coll} if crashed, 0 otherwise |
| R_{speed} | ${C}_{speed} \frac{vehicle\_speed}{max\_speed}$ |
| R_{right-lane} | C_{right-lane} if on the right lane, 0 otherwise |
| R_{merging} | $\begin{matrix}{C}_{merging} \frac{target\_speed - current\_speed}{target\_speed} if on the merging \\ lane , 0 otherwise\end{matrix}$ |
| R_{lane-change} | C_{lane-change} if vₜ^{H} is move_left or move_right, 0 otherwise |
| R_{distraction} | C_{distraction} if the simulated driver is in a distracted state, 0 |
| | otherwise |
| Rₐₗₑᵣₜ | Cₐₗₑᵣₜ if vₜ^{A} = no_alert and dₜ − 1 = 0, 0 otherwise |
| R_{accept-alert} | C_{accept-alert} if vₜ^{A} = alert with dₜ − 1 = 1 and dₜ = 0, 0 |
| | otherwise |

In Table 1, R_{coll}, Rs_{peed}, R_{right-lane}, R_{merging}, and R_{lane-change} are the reward components pertaining to driving performance. R_{distraction} pertains to the human tendency to be distracted, and Rₐₗₑᵣₜ capture the rewards the adaptive HMI system 18 receives for issuing sparse alerts. R_{accept-alert} is the reward term that connects the adaptive HMI system 18 to the simulated human driver 14. For training the models, the coefficients may be set related to driving rewards to values such that the vehicle favors being safe on the right lane at higher speeds and seeks to minimize lane changes.

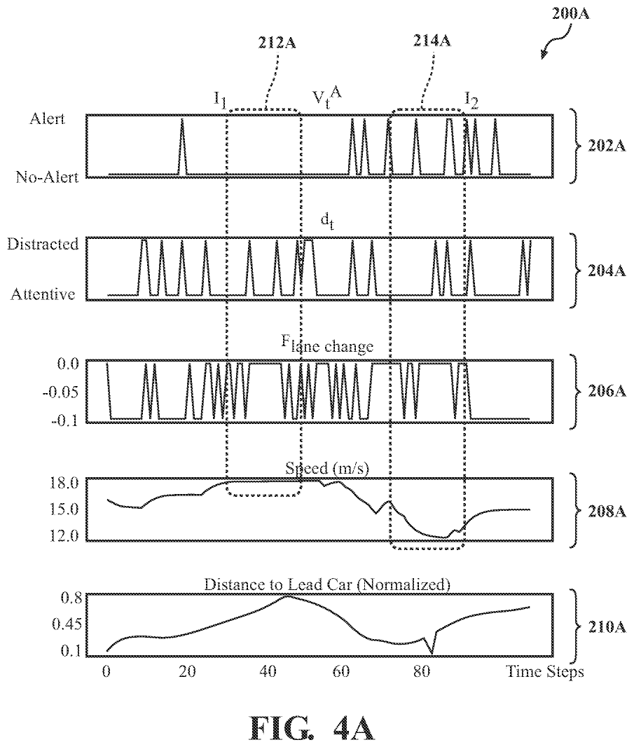

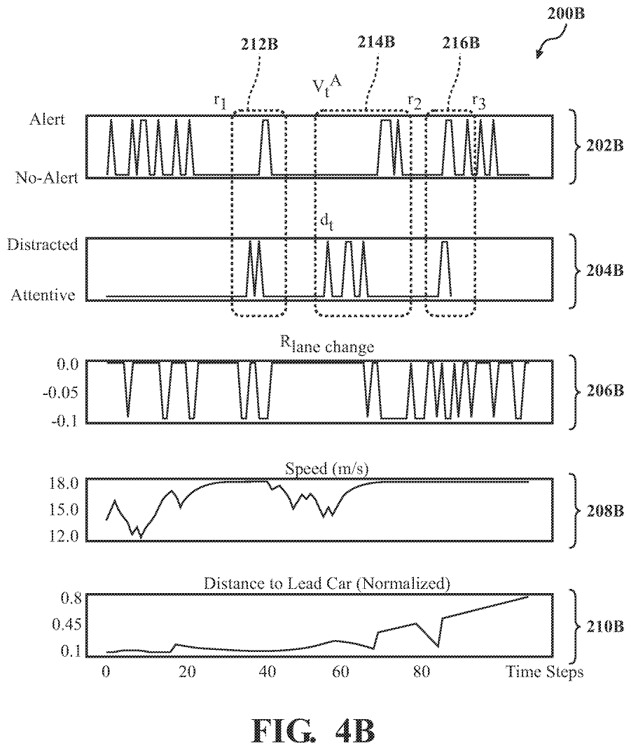

FIGS. 4A and 4B illustrate output traces 200A and 200B from two different simulated human models and the output of adaptive HMI systems of policies trained utilizing the training system described above. The parameters of the policies that represent the simulated human models represent different types of human drivers. For example, FIG. 4A utilizes parameters representing a first driver (Driver 1) who is less cautious and less willing to accept the adaptive HMI systems alerts.

Conversely, FIG. 4B utilizes parameters representing a second driver (Driver 2) who is more cautious and more willing to accept the adaptive HMI systems alerts. Additionally, different settings of Cₐₗₑᵣₜ varied the alert sparsity to indirectly encode a driver's preference to be alerted.

The traces 200A and 200B include alert traces 202A, 202B (traces that indicate if an alert is being output by the adaptive HMI system), distracted traces 204A, 204B (traces that indicate if the driver is distracted or not), vehicle speed traces 206A, 206B (speed of the simulated vehicle 15), distance to the lead car 208A, 208B (distance to a vehicle forward of the simulated vehicle 15), and time steps 210A, 210B.

FIGS. 4A and 4B illustrate that Driver 2 is distracted less often than Driver 1 due to their higher willingness (higher value of γ) to accept the alerts of the adaptive HMI system despite the baseline distraction probability β being the same for both. Also shown is a trend where the interventions of the adaptive HMI system are more active when driving-related rewards decrease, as indicated in boxes 212A and 214A.

For example, although Driver 1 gets distracted during the initial part of the trajectory, the interventions of the adaptive HMI system remain sparse, likely because the vehicle speed is still fairly high. However, immediately after the halfway mark, there is a decrease in speed and a corresponding increase in the number of interventions by the adaptive HMI system. Also shown, especially for Driver 2, when the driver becomes distracted, the adaptive HMI system issues a slightly delayed alert, particularly when driving-related rewards decrease, as illustrated in boxes 212B, 214B, and 216B.

TABLE 1
Metrics for models trained for two different driver types.
For all models, (α, β) = (0.6, 0.4) Driver parameters
are the same as in FIGS. 4A and 4B.

| | Cₐₗₑᵣₜ = 3.0 | | Cₐₗₑᵣₜ = 6.0 | | Cₐₗₑᵣₜ = 9.0 | |
|---|---|---|---|---|---|---|
| | Driver 1 | Driver 2 | Driver 1 | Driver 2 | Driver 1 | Driver 2 |
| High-Speed | 438 | 444 | 424 | 382 | 430 | 372 |
| Reward | | | | | | |
| Distraction | −316 | −39 | −330 | −89 | −349 | −98 |
| Reward | | | | | | |
| Lane Change | −2.90 | −2.97 | −3.2 | −4.6 | −4.0 | −3.7 |
| Reward | | | | | | |
| Minimum TTC to | 0.48 | 0.19 | 0.49 | 0.22 | 0.52 | 0.26 |
| Lead Vehicle (s) | | | | | | |
| Number of Alert | 7.0 | 4.6 | 5.7 | 6.8 | 5.4 | 7.2 |
| Acceptances | | | | | | |

Table 2 presents different driving performance-related metrics for Driver 1 and Driver 2 for models trained with different Cₐₗₑᵣₜ coefficients. The adaptive HMI system is more effective in making Driver 2 less distracted, indicating that the learned policy can intervene effectively and make the driver more attentive. The average high-speed reward tends to be lower for Driver 2, when Cₐₗₑᵣₜ=6.0 and 9.0. Visual inspection of the roll-outs also reveals that Driver 2 exhibits more speed variations and can regulate the speed depending on how close the nearby vehicles are. The adaptive HMI system can help Driver 2 to be more cautious, even though there is a high probability of being distracted. Lane change rewards are also comparable between the driver type (except for Cₐₗₑᵣₜ=6.0), indicating that the alerts are not inadvertently causing fishtailing behavior. Also, with respect to the minimum Time-To-Collision (TTC) for the different driver types, Driver 2 can achieve lower TTC compared to Driver 1, suggesting that if the driver is more receptive to the alerts from the adaptive HMI system, the joint human-AI team is likely more confident in following the lead car more closely.

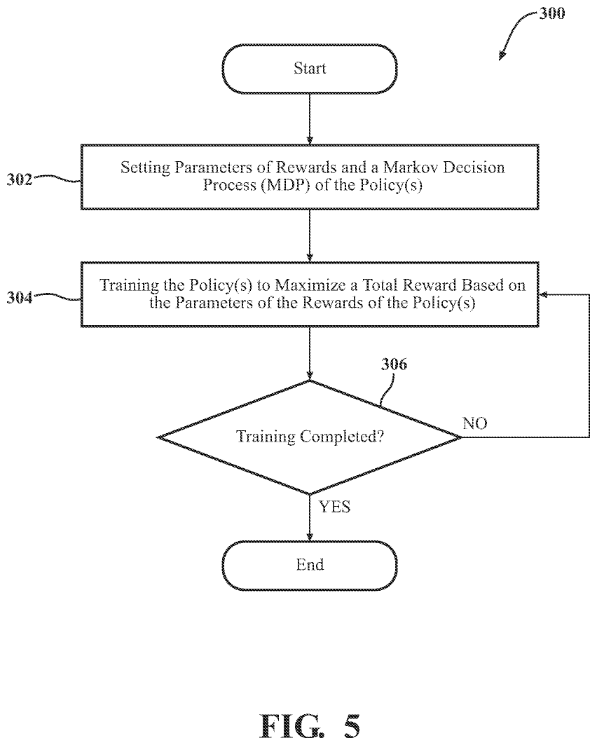

Referring to FIG. 5, a method 300 for training at least one policy using a framework for encoding human behaviors and preferences in a driving environment is shown. The method 300 will be described from the viewpoint of the training system 100 of FIG. 2. However, it should be understood that this is just one example of implementing the method 300. While method 300 is discussed in combination with the training system 100, it should be appreciated that the method 300 is not limited to being implemented within the training system 100 but is instead one example of a system that may implement the method 300. Additionally, it should be understood that the method 300 may include other aspects previously described in the paragraphs above that are not specifically described when referring to the method 300. For example, numerous aspects and actions of the training system 100 have been previously described. Any of these aspects and actions may be incorporated within the method 300.

In step 302, the training module 122 causes the processor(s) 110 to set parameters of rewards and a MDP of the one or more policies 134. One or more policies, as explained earlier, model the simulated human driver 14 of a simulated vehicle 15 and adaptive HMI system 18. Again, the simulated human driver 14 and the adaptive HMI system 18 are configured to interact with each other. In some cases, the one or more policies 134 may be separate, wherein one policy models the behavior of the simulated human driver 14, while the other policy models the behavior of the adaptive HMI system 18. In another example, instantly using separate policies, the one or more policies 134 may be a single joint policy that models both the simulated human driver 14 and the adaptive HMI system 18.

The actions of the at least one policy 134 may include human-initiated vehicle actions by the simulated human driver and intervention actions by the adaptive HMI system. The human-initiated vehicle actions may include speeding up the simulated vehicle 15, slowing down the simulated vehicle 15, causing the simulated vehicle 15 to move left, causing the simulated vehicle 15 to move right, and/or maintaining the speed of the simulated vehicle 15. The intervention actions may include providing an alert to the simulated human driver and not providing the alert to the simulated human driver.

The parameters of the rewards of the at least one policy 134 may include cautiousness exhibited by the simulated human driver, a likelihood of the simulated human driver becoming distracted and attentive, and a willingness of the simulated human driver to be influenced by an external alert issued by the adaptive HMI system.

Once the parameters are set, the method 300 proceeds to step 304, wherein training module 122 causes the processor(s) 110 to train the at least one policy 134 to maximize the total reward based on the parameters of rewards of the at least one policy 134. The method 300 may also include step 306, which determines if the training is complete. If the training is complete, the method 300 ends. Otherwise, the method 300 continues training until complete.

The systems and methods described herein allow for the training of at least one policy using a framework for encoding human behaviors and preferences in a driving environment. The framework accelerates the development of adaptive AI systems that can respond to individual driver states, traits, and preferences by serving as a data generation engine and training environment for learning personalized human AI teaming policies. The framework supports modeling human behaviors and their preferences for receiving AI assistance to support various tasks such as data generation, algorithm prototyping, and learning interaction policies.

Detailed embodiments are disclosed herein. However, it is to be understood that the disclosed embodiments are intended only as examples. Therefore, specific structural and functional details disclosed herein are not to be interpreted as limiting but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in the figures, but the embodiments are not limited to the illustrated structure or application.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of order noted in the figures. For example, two blocks shown in succession may be executed substantially concurrently, or the blocks may sometimes be executed in the reverse order, depending upon the functionality involved.

In one or more arrangements, one or more of the modules described herein can include artificial or computational intelligence elements, e.g., neural networks, fuzzy logic, or other machine learning algorithms. Further, in one or more arrangements, one or more of the modules can be distributed among a plurality of the modules described herein. In one or more arrangements, two or more of the modules described herein can be combined into a single module.

The systems, components and/or processes described above can be realized in hardware or a combination of hardware and software. They can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein. The systems, components, and/or processes also can be embedded in computer-readable storage, such as a computer program product or other data programs storage device, readable by a machine, tangibly embodying a program of instructions executable by the machine to perform methods and processes described herein. These elements also can be embedded in an application product that comprises all the features enabling the implementation of the methods described herein and which, when loaded in a processing system, can carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but is not limited to, an electronic, magnetic, optical, electromagnetic, infrared, or semiconductor system, apparatus, device, or any suitable combination of the preceding. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the preceding. In the context of this document, a computer-readable storage medium may be any tangible medium that can contain or store a program for use by or in connection with an instruction execution system, apparatus, or device.

Generally, the term “module,” as used herein, includes routines, programs, objects, components, data structures, and so on that perform particular tasks or implement particular data types. In further aspects, a memory generally stores the noted modules. The memory associated with a module may be a buffer or cache embedded within a processor, RAM, ROM, flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, RF, etc., or any suitable combination of the preceding. Computer program code for carrying out operations for aspects of the present arrangements may be written in any combination of one or more programming languages, including an object-oriented programming language such as Java™, Smalltalk, C++, or the like, and conventional procedural programming languages, such as the “C” programming language or similar programming languages. The program code may execute entirely on the user's computer, partly on the user's computer, as a stand-alone software package, partly on a remote computer, or entirely on the remote computer or server. In the latter scenario, the remote computer may be connected to the user's computer through any network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . . ” as used herein refers to and encompasses any and all possible combinations of one or more of the associated listed items. For example, the phrase “at least one of A, B, and C” includes A only, B only, C only, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A method for training at least one policy using a framework for encoding human behaviors and preferences in a driving environment, the method comprising steps of:
setting parameters of rewards and a Markov Decision Process (MDP) of the at least one policy, the at least one policy models a simulated human driver of a simulated vehicle and an adaptive human-machine interface (HMI) system, the simulated human driver and the adaptive HMI system configured to interact with each other; and
training the at least one policy to maximize a total reward based on the parameters of the rewards of the at least one policy.

2. The method of claim 1, wherein the driving environment is a simulated road environment.

3. The method of claim 1, wherein actions of the at least one policy includes human-initiated vehicle actions by the simulated human driver and intervention actions by the adaptive HMI system.

4. The method of claim 3, wherein the human-initiated vehicle actions include speeding up the simulated vehicle, slowing down the simulated vehicle, causing the simulated vehicle to move left, causing the simulated vehicle to move right, and maintaining the speed of the simulated vehicle.

5. The method of claim 4, wherein the intervention actions include providing an alert to the simulated human driver and not providing the alert to the simulated human driver.

6. The method of claim 1, wherein the parameters of the rewards of the at least one policy include cautiousness exhibited by the simulated human driver, a likelihood of the simulated human driver becoming distracted and attentive, and a willingness of the simulated human driver to be influenced by an external alert issued by the adaptive HMI system.

7. The method of claim 1, wherein the at least one policy is one of:
a joint policy modeling actions of the simulated human driver and the adaptive HMI system; and
separate policies that separately model actions of the simulated human driver and the adaptive HMI system.

8. A system for training at least one policy using a framework for encoding human behaviors and preferences in a driving environment, the system comprising:
a processor; and
a memory in communication with the processor, the memory storing instructions that, when executed by the processor, cause the processor to:
set parameters of rewards and a Markov Decision Process (MDP) of the at least one policy, the at least one policy models a simulated human driver of a simulated vehicle and an adaptive human-machine interface (HMI) system, the simulated human driver and the adaptive HMI system configured to interact with each other, and
train the at least one policy to maximize a total reward based on the parameters of the rewards of the at least one policy.

9. The system of claim 8, wherein the driving environment is a simulated road environment.

10. The system of claim 8, wherein actions of the at least one policy includes human-initiated vehicle actions by the simulated human driver and intervention actions by the adaptive HMI system.

11. The system of claim 10, wherein the human-initiated vehicle actions include speeding up the simulated vehicle, slowing down the simulated vehicle, causing the simulated vehicle to move left, causing the simulated vehicle to move right, and maintaining the speed of the simulated vehicle.

12. The system of claim 11, wherein the intervention actions include providing an alert to the simulated human driver and not providing the alert to the simulated human driver.

13. The system of claim 8, wherein the parameters of the rewards of the at least one policy include cautiousness exhibited by the simulated human driver, a likelihood of the simulated human driver becoming distracted and attentive, and a willingness of the simulated human driver to be influenced by an external alert issued by the adaptive HMI system.

14. The system of claim 8, wherein the at least one policy is one of:
a joint policy modeling actions of the simulated human driver and the adaptive HMI system; and
separate policies that separately model actions of the simulated human driver and the adaptive HMI system.

15. A non-transitory computer-readable medium storing instructions for training at least one policy using a framework for encoding human behaviors and preferences in a driving environment that, when executed by one or more processors, cause the one or more processors to:
set parameters of rewards and a Markov Decision Process (MDP) of the at least one policy, the at least one policy models a simulated human driver of a simulated vehicle and an adaptive human-machine interface (HMI) system, the simulated human driver and the adaptive HMI system configured to interact with each other; and
train the at least one policy to maximize a total reward based on the parameters of the rewards of the at least one policy.

16. The non-transitory computer-readable medium of claim 15, wherein the driving environment is a simulated road environment.

17. The non-transitory computer-readable medium of claim 15, wherein actions of the at least one policy includes human-initiated vehicle actions by the simulated human driver and intervention actions by the adaptive HMI system.

18. The non-transitory computer-readable medium of claim 17, wherein the human-initiated vehicle actions include speeding up the simulated vehicle, slowing down the simulated vehicle, causing the simulated vehicle to move left, causing the simulated vehicle to move right, and maintaining the speed of the simulated vehicle.

19. The non-transitory computer-readable medium of claim 18, wherein the intervention actions include providing an alert to the simulated human driver and not providing the alert to the simulated human driver.

20. The non-transitory computer-readable medium of claim 15, wherein the parameters of the rewards of the at least one policy include cautiousness exhibited by the simulated human driver, a likelihood of the simulated human driver becoming distracted and attentive, and a willingness of the simulated human driver to be influenced by an external alert issued by the adaptive HMI system.
